(19) United States
(12) Patent Application Publication
(10) Pub. No.: US 2024/0389271 A1
(43) Pub. Date: Nov. 21, 2024

(54) HEAT TRANSFER MEMBER

(71) Applicant: YAZAKICORPORATION, Tokyo (JP)

(72) Inventors: Junya HIGASHI, Shizuoka (JP); Hideki MIZUNO, Shizuoka (JP)

(73) Assignee: YAZAKICORPORATION, Tokyo (JP)

(21) Appl. No.: 18/659,426

(22) Filed: May 9, 2024

(30) Foreign Application Priority Data
May 15, 2023 (JP) 2023-079896

(51) Int. Cl. H05K 7/20

(52) U.S. Cl. CPC H05K 7/2039

(57) ABSTRACT

A heat transfer member includes a heat transfer element which is arranged between a heating element and a cooling body, and transfers heat of the heating element to the cooling body. The heat transfer element includes a high content part which includes a heat transfer material and comes into contact with the heating element, and a low content part which is a lower content of the heat transfer material than the high content part and arranged around the high content part.

### CROSS-REFERENCE TO RELATED APPLICATIONS

The present application is based on, and claims priority from Japanese Patent Application No. 2023-079896, filed on May 15, 2023, the entire contents of which are incorporated herein by reference.

### TECHNICAL FIELD

The present application relates to a heat transfer member.

### BACKGROUND

JP 2020-127302 A (PTL 1) discloses a heat transfer member that is arranged between a bus bar as a heating element and a bottom wall as a cooling element, and including an insulating member as a heat transfer element for transferring heat of the bus bar to the bottom wall. The insulating member transfers heat generated by the bus bar to the bottom wall, and cools the bus bar.

### SUMMARY

As a heat transfer member as disclosed in PTL 1, the heat transfer body is constituted of one kind of member excellent in heat conductivity. The member excellent in heat conductivity increases in cost because it contains many expensive heat transfer materials.

The present application has been made in view of the problem described above. An object of the present application is to provide a heat transfer member which can be reduced in cost.

A heat transfer member according to an embodiment includes a heat transfer element which is arranged between a heating element and a cooling body, and transfers heat of the heating element to the cooling body. The heat transfer element includes a high content part which includes a heat transfer material and comes into contact with the heating element, and a low content part which is a lower content of the heat transfer material than the high content part and arranged around the high content part.

The present application makes it possible to provide a heat transfer member which can be reduced in cost.

### BRIEF DESCRIPTION OF THE DRAWINGS

FIG. 1 is a top view of a heat transfer member according to an embodiment.

FIG. 2 is an enlarged sectional view of a main portion of the heat transfer member according to the embodiment.

FIG. 3 is a sectional view when the heat transfer member according to the embodiment is arranged between a heating element and a cooling element.

### DETAILED DESCRIPTION

Hereinafter, a heat transfer member according to an embodiment will be described in detail with reference to the drawings. Note that the dimensional ratio of the drawings is exaggerated for the sake of explanation, and may differ from the actual ratio.

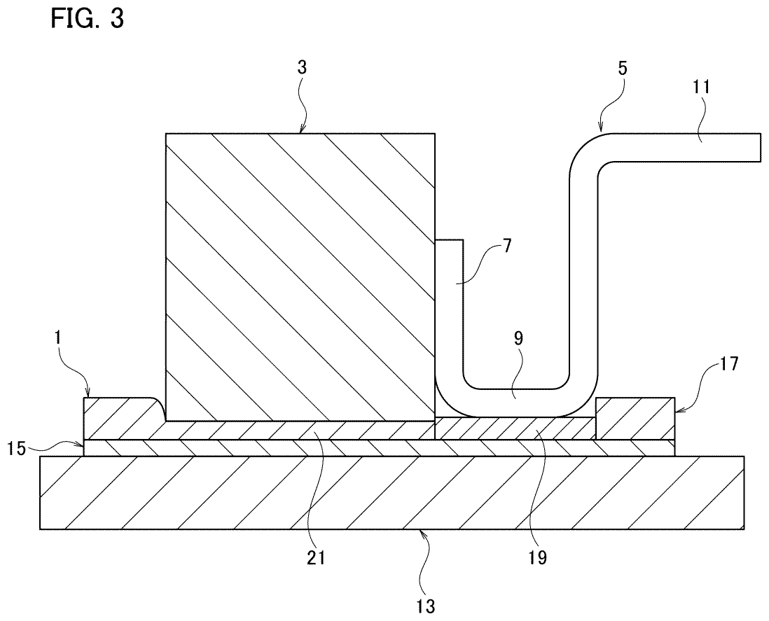

As illustrated in FIG. 3, a heat transfer member 1 according to an embodiment is applied so as to cool an electrical component 3 such as a relay, a fuse, a pyro-switch, or an electronic substrate. The electrical component 3 includes a heating element 5 such as a bus bar that generates heat by energization.

The heating element 5 is made of a conductive material, and includes a component connection part 7, a contact part 9, and an electrical connection part 11. The component connection part 7 is electrically connected to the electrical component 3, and exposed to the outer side of the electrical component 3. The contact part 9 is formed of one material which is continuous with the component connection part 7, and extends so as to be separated from the electrical component 3 from the lower end of the component connection part 7. The electrical connection part 11 is formed of one material which is continuous with the contact part 9, and extends upward from the end of the contact part 9, and then extends so as to be separated from the electrical component 3. The electrical connection part 11 is electrically connected to a mating terminal (not illustrated) which is electrically connected to another electrical component (not illustrated), for example.

The heating element 5 generates heat by energizing the electrical component 3, and when the contact part 9 comes into contact with the heat transfer member 1, the heat of the heating element 5 is transferred to a cooling body 13 provided on a wall part of a case through the heat transfer member 1, for example. The cooling body 13 may have any structure, such as a structure having fins in contact with outside air, or a structure in which refrigerants flow inside. Further, a sheet-like insulating member 15 made of an insulating material is arranged between the heat transfer member 1 and the cooling body 13 so as to maintain the insulating property; however, the insulating member 15 need not be arranged if the insulating property can be maintained only by the heat transfer member 1.

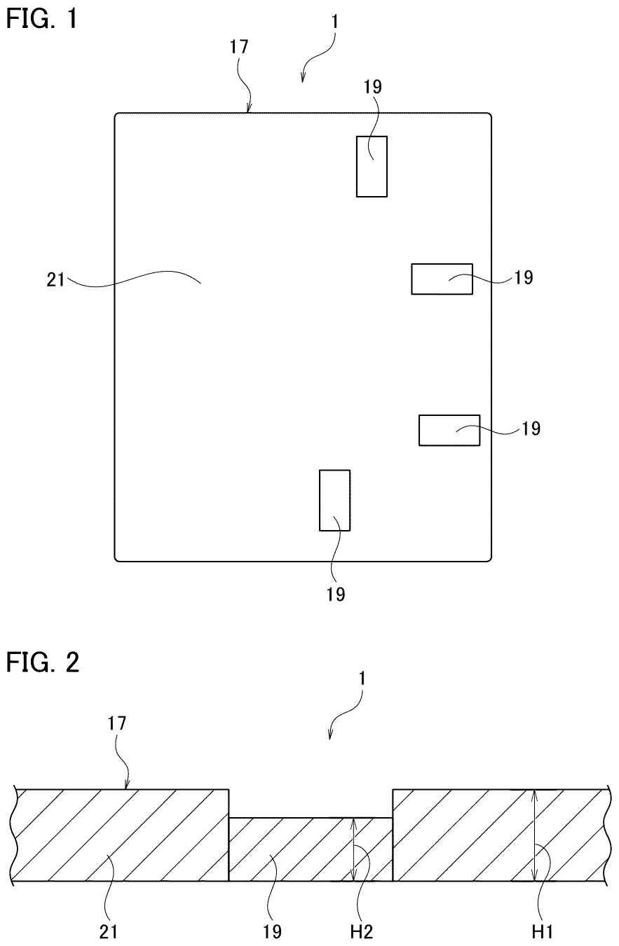

As illustrated in FIGS. 1 to 3, the heat transfer member 1 includes a sheet-like heat transfer element 17 which is arranged between the electrical component 3 and the cooling body 13. The heat transfer element 17 includes a high content part 19 and a low content part 21.

The high content part 19 has a high content of a heat transfer material such as alumina balls with respect to an insulating material such as a synthetic resin, for example, and is a hard part which is difficult to deform. The high content part 19 has a high content of the heat transfer material, and is therefore excellent in heat conductivity. The high content part 19 comes into contact with the contact part 9 of the heating element 5, and transfers the heat of the heating element 5 to the cooling body 13. This makes it possible to transfer the heat of the heating element 5 to the cooling body 13 in a stable manner, thereby maintaining high heat conductivity. Although a plurality of high content parts 19 are provided in the heat transfer element 17, the number of high content parts 19 may be determined to correspond to the number of heating elements 5 to be arranged.

For example, the low content part 21 has a low content of a heat transfer material such as alumina balls with respect to an insulating material such as a synthetic resin, has a lower hardness than the high content part 19, and is a soft part that can be elastically deformed. The low content part 21 may form a gel-like insulating material containing the heat transfer material into a sheet. Since the low content part 21 has a low content of a heat transfer material which is expensive, it is less expensive than the high content part 19. The low content part 21 is integrally provided with the high content part 19 around the high content part 19. Since the low content part 21 is elastically deformable, it is excellent in shock absorption. The main body of the electrical component 3 is arranged on the low content part 21, and for example, the low content part 21 absorbs external force applied to the electrical component 3 by means of vibration or the like, thereby maintaining contact between the high content part 19 and the contact part 9 of the heating element 5. For this reason, the heat of the heating element 5 can be transferred to the cooling body 13 in a stable manner. In addition, the low content part 21 contains a heat transfer material, which transfers the heat of the main body of the electrical component 3 to the cooling body 13.

The heat transfer element 17 includes the high content part 19 and the low content part 21, which makes it possible for the high content part 19 to maintain the heat conductivity of the heating element 5 to the cooling body 13, and for the low content part 21 to reduce the cost.

The low content part 21 has a larger amount of occupancy set in the heat transfer element 17 than the high content part 19. For example, in the whole area of the heat transfer element 17, the occupied area of the low content part 21 is set larger than the occupied area of the high content part 19. In addition, the height H1 of the low content part 21 is set higher than the height H2 of the high content part 19 between the heating element 5 (electrical component 3) and the cooling body 13. The low content part 21 has a larger amount of occupancy set in the heat transfer element 17 than the high content part 19, which increases an amount of occupancy of the low content part 21 which is inexpensive, thereby making it possible to reduce the cost.

Thus, the heat transfer member 1 includes the heat transfer element 17 which is arranged between the heating element 5 and the cooling body 13, and transfers the heat of the heating element 5 to the cooling body 13. The heat transfer element 17 includes the high content part 19 which includes a heat transfer material and comes into contact with the heating element 5, and the low content part 21 which is a lower content of the heat transfer material than the high content part 19 and arranged around the high content part 19.

This makes it possible for the high content part 19 to maintain the heat conductivity of the heating element 5 to the cooling body 13, and for the low content part 21 to reduce the cost.

Accordingly, the heat transfer member 1 can be reduced in cost.

The heating element 5 is electrically connected to the electrical component 3. The electrical component 3 is arranged on the low content part 21.

The low content part 21 is softer than the high content part 19, which makes it possible to absorb the external force applied to the electrical component 3, thereby maintaining contact between the high content part 19 and the heating element 5. This makes it possible to transfer the heat of the heating element 5 to the cooling body 13 in a stable manner.

In addition, the low content part 21 has a larger amount of occupancy set in the heat transfer element 17 than the high content part 19.

This increases an amount of occupancy of the low content part 21 which is inexpensive, thereby making it possible to reduce the cost.

Although the embodiment has been described as above, the embodiment is not limited thereto, and various modifications can be made within a scope of the gist of the present embodiment.

For example, although the height H1 of the low content part 21 is set higher than the height H2 of the high content part 19, the present application is not limited thereto. For example, the height H1 of the low content part 21 may be set lower than the height H2 of the high content part 19. In this case, it is preferable to set the height H1 of the low content part 21 such that the external force applied to the electrical component 3 can be absorbed.

1. A heat transfer member, comprising:
a heat transfer element which is arranged between a heating element and a cooling body, and transfers heat of the heating element to the cooling body,
the heat transfer element comprising a high content part which includes a heat transfer material and comes into contact with the heating element, and a low content part which is a lower content of the heat transfer material than the high content part and arranged around the high content part.

2. The heat transfer member according to claim 1, wherein
the heating element is electrically connected to an electrical component, and the electrical component is arranged on the low content part.

3. The heat transfer member according to claim 1, wherein
the low content part has a larger amount of occupancy set in the heat transfer element than the high content part.

4. The heat transfer member according to claim 1, wherein
the low content part has a lower hardness than the high content part.
